(19) United States
(12) Patent Application Publication
(10) Pub. No.: US 2025/0274099 A1
(43) Pub. Date: Aug. 28, 2025

(54) Bulk Acoustic Wave Resonator and Method for Manufacturing therefor

(71) Applicant: Wuhan MEMSonics Technologies Co.,Ltd., Wuhan (CN)

(72) Inventors: Bowoon SOON, Wuhan (CN); Jie ZHOU, Wuhan (CN); Bensong PI, Wuhan (CN); Chengliang SUN, Wuhan (CN)

(73) Assignee: Wuhan MEMSonics Technologies Co.,Ltd., Wuhan (CN)

(21) Appl. No.: 18/979,100

(22) Filed: Dec. 12, 2024

(30) Foreign Application Priority Data
Feb. 27, 2024 (CN) 202410217185.5

(51) Int. Cl. H03H 9/17; H03H 3/02

(52) U.S. Cl. CPC H03H 9/173; H03H 3/02; H03H 2003/021

(57) ABSTRACT

A bulk acoustic wave resonator and a method for manufacturing therefor are provided. The bulk acoustic wave resonator includes a substrate, a lower conductive layer, a piezoelectric layer, and an upper conductive layer. At least one first cavity located between the upper conductive layer and the piezoelectric layer is provided at a boundary of an overlapping area. A plurality of first support columns are provided in the at least one first cavity. The plurality of first support columns are used for dividing the at least one first cavity into a plurality of through holes at least partially located in the overlapping area. The plurality of through holes are arranged in a direction from a center of the overlapping area to the boundary.

### TECHNICAL FIELD

The present application relates to the technical field of resonators, and in particular to a bulk acoustic wave resonator and a method for manufacturing therefor.

### BACKGROUND

A radio frequency filter is a core component of a radio frequency front end applied in the field of wireless communications. A resonator is a key component of a radio frequency filter, and is also a basic unit. Resonators currently applied to the radio frequency market include surface acoustic wave resonators and bulk acoustic wave resonators. The bulk acoustic wave resonators gradually become the mainstream of the market due to the advantages of high resonance frequency, high quality factor, high electromechanical coupling coefficient, high power capacity, low loss, small volume, and compatibility with semiconductor technology.

After an alternating current is applied to an electrode of the bulk acoustic wave resonator, a longitudinal vibration is mainly generated, and other transverse acoustic waves are excited at the same time, thereby causing energy leakage. Furthermore, heat is generated inside the resonator, which greatly affects the reliability of the device.

### SUMMARY

The present application provides a bulk acoustic wave resonator and a method for manufacturing the bulk acoustic wave resonator.

The embodiments of the present application use the following technical solutions:
according to one aspect of the embodiments of the present application, provided is a bulk acoustic wave resonator, including a substrate, and a lower conductive layer, a piezoelectric layer and an upper conductive layer which are sequentially stacked on the substrate, and the lower conductive layer, the piezoelectric layer and the upper conductive layer have an overlapping area in a stacking direction; at least one first cavity located between the upper conductive layer and the piezoelectric layer is provided at a boundary of the overlapping area; a plurality of first support columns are provided in the at least one first cavity, the plurality of first support columns are used for dividing the at least one first cavity into a plurality of through holes at least partially located in the overlapping area; and the plurality of through holes are arranged in a direction from a center of the overlapping area to the boundary of the overlapping area.

Optionally, there are a plurality of first cavities, each of the plurality of first cavities is provided with the plurality of through holes, the plurality of first cavities are arranged at intervals along the boundary of the overlapping area, a connection cavity located between the upper conductive layer and the piezoelectric layer is provided between two adjacent first cavities, and the two adjacent first cavities are in communication with each other through the connection cavity.

Optionally, among the plurality of first cavities, at least two first cavities include different numbers of through holes.

Optionally, the plurality of through holes includes at least one of the following:
at least one first through hole located in the overlapping area and at least one second through hole located outside the overlapping area;
a third through hole crossing the boundary of the overlapping area.

Optionally, a second cavity is provided between the substrate and the lower conductive layer;
orthographic projections, in the stacking direction, of the plurality of through holes are located in the second cavity;
or, orthographic projections, in the stacking direction, of some through holes of the plurality of through holes are located in the second cavity, and orthographic projections, in the stacking direction, of the other through holes of the plurality of through holes do not overlap with an orthographic projection of the second cavity in the stacking direction.

Optionally, the piezoelectric layer and the lower conductive layer are provided with at least one release hole which is in communication with the second cavity, and the at least one release hole is located outside the overlapping area.

Optionally, each of the plurality of through holes has a width in the direction from the center of the overlapping area to the boundary of the overlapping area, and at least some of the plurality of through holes have different widths.

Optionally, the upper conductive layer has an anchor portion, the anchor portion is located on the at least one first cavity, and a surface of one side of the anchor portion away from the piezoelectric layer is an undulating surface.

Optionally, the upper conductive layer includes an upper electrode located in the overlapping area and an upper electrode lead-out portion located outside the overlapping area, a peripheral edge of the upper electrode is composed of a first edge and a second edge, and the upper electrode is connected to the upper electrode lead-out portion by means of the first edge; and the at least one first cavity is located at the first edge, or the at least one first cavity is located at the first edge and the second edge.

Optionally, at least one third cavity is provided between the upper electrode and the piezoelectric layer, and the at least one third cavity is located at the second edge.

Optionally, a side of the at least one third cavity away from the center of the overlapping area is closed by at least one second support column supported between the upper electrode and the piezoelectric layer.

Optionally, at least one third support column supported between the upper electrode and the piezoelectric layer is provided in the third cavity.

Optionally, there are a plurality of third cavities, and the plurality of third cavities are arranged at intervals along the second edge.

Optionally, when a second cavity is provided between the substrate and the lower conductive layer, an orthographic projection of the at least one third cavity in the stacking direction is located in the second cavity.

Optionally, each of the plurality of through holes has a width in the direction from the center of the overlapping area to the boundary of the overlapping area, the at least one third cavity has a width in the direction from the center of the overlapping area to the boundary of the overlapping area, and the width of the at least one third cavity is greater than a sum of widths of any two through holes and less than a sum of widths of any three through holes.

Optionally, the upper conductive layer has an anchor portion located on the at least one first cavity, the anchor portion has a first surface away from one side of the piezoelectric layer, the upper conductive layer has a wing portion located on the at least one third cavity, the wing portion has a second surface away from one side of the piezoelectric layer, and a maximum spacing between the first surface and a back surface of the substrate is different from a maximum spacing between the second surface and the back surface of the substrate.

Optionally, when the piezoelectric layer and the lower conductive layer are provided with at least one release hole in communication with the second cavity, an orthographic projection of the at least one release hole in the stacking direction are located outside an orthographic projection of the upper electrode lead-out portion in the stacking direction.

Optionally, the at least one third cavity is spaced apart from an endpoint of the first edge by a first distance, the first distance is greater than 5 microns.

According to another aspect of the embodiments of the present application, provided is a method for manufacturing a bulk acoustic wave resonator, including:
a lower conductive layer and a piezoelectric layer are formed on a substrate;
a plurality of first sacrificial portions, an upper conductive layer covering the plurality of first sacrificial portions, and a plurality of first support columns each of which filled between two adjacent first sacrificial portions are formed on the piezoelectric layer, and the lower conductive layer, the piezoelectric layer and the upper conductive layer have an overlapping area in an overlapping direction, the plurality of first sacrificial portions are at least partially located in the overlapping area, and the plurality of first sacrificial portions are arranged at intervals in a direction from a center of the overlapping area to a boundary of the overlapping area; and
the plurality of first sacrificial portions are released to form at least one first cavity between the upper conductive layer and the piezoelectric layer, and the at least one first cavity is divided by the plurality of first support columns into a plurality of through holes arranged in the direction from the center of the overlapping area to the boundary of the overlapping area.

Optionally, the plurality of first sacrificial portions, the upper conductive layer covering the plurality of first sacrificial portions, and the plurality of first support columns each of which filled between two adjacent first sacrificial portions are formed on the piezoelectric layer includes:
a first sacrificial layer is formed on the piezoelectric layer;
the first sacrificial layer is etched to form the plurality of first sacrificial portions and a second sacrificial portion; and
an upper conductive layer covering the plurality of first sacrificial portions and the second sacrificial portion, and the plurality of first support column each of which filled between two adjacent first sacrificial portions are formed on the piezoelectric layer, and the second sacrificial portion is used for releasing to form at least one third cavity located between the upper conductive layer and the piezoelectric layer, the upper conductive layer includes an upper electrode located in the overlapping area and an upper electrode lead-out portion located outside the overlapping area, a peripheral edge of the upper electrode is composed of a first edge and a second edge, the upper electrode is connected to the upper electrode lead-out portion by means of the first edge, and the at least one third cavity is located at the second edge; and the at least one first cavity is located at the first edge, or the at least one first cavity is located at the first edge and the second edge.

### BRIEF DESCRIPTION OF THE DRAWINGS

In order to more clearly illustrate the technical solutions of the present disclosure, drawings which need to be used therein will be introduced below briefly. It should be understood that the drawings below merely show some embodiments of the present application, and therefore should not be considered as limitation to the scope. Those ordinarily skilled in the art still could obtain other relevant drawings according to these drawings, without using any creative efforts.

FIG. 1 is a first state schematic diagram of a method for manufacturing a bulk acoustic resonator provided in an embodiment of the present application;

FIG. 2 is a top view of a second cavity shown in FIG. 1;

FIG. 3 is a second state schematic diagram of a method for manufacturing a bulk acoustic wave resonator provided in an embodiment of the present application;

FIG. 4 is a third state schematic diagram of a method for manufacturing a bulk acoustic wave resonator provided in an embodiment of the present application;

FIG. 5 is a top view of a sacrificial layer to be released in FIG. 4;

FIG. 6 is a fourth state schematic diagram of a method for manufacturing a bulk acoustic wave resonator provided in an embodiment of the present application;

FIG. 7 is a top view of a thickening layer of FIG. 6;

FIG. 8 is a fifth state schematic diagram of a method for manufacturing a bulk acoustic wave resonator provided in an embodiment of the present application;

FIG. 9 is a top view of an upper conductive layer in FIG. 8;

FIG. 10 is a schematic structural diagram of a bulk acoustic wave resonator provided in an embodiment of the present application;

FIG. 11 is a top view of another sacrificial layer to be released provided in an embodiment of the present application;

FIG. 12 is a top view of yet another sacrificial layer to be released provided in an embodiment of the present application;

FIG. 13 is a top view of still another sacrificial layer to be released provided in an embodiment of the present application;

FIG. 14 is a partial enlarged view of FIG. 13;

FIG. 15 is a partial enlarged view of FIG. 13;

FIG. 16 is a schematic diagram of a relationship between parameters and an effective electromechanical coupling factor of a bulk acoustic resonator provided in an embodiment of the present application; and

FIG. 17 is a schematic diagram of a relationship between parameters and a quality factor of a bulk acoustic resonator provided in an embodiment of the present application.

Reference signs: 201, substrate; 202, second cavity; 203, second sacrificial layer; 204, seed layer; 205, lower conductive layer; 206, piezoelectric layer; 2071, first sacrificial portion; 2072, second sacrificial portion; 2073, third sacrificial portion; 2077, gap; 208, lower conductive layer lead-out hole; 209, thickening layer; 210, upper conductive layer; 2101, anchor portion; 2102, wing portion; 2103, first support column; 2104, second support column; 2105, upper electrode; 2106, upper electrode lead-out portion; 2107, third support column; 211, protective layer; 212, release hole; 213, third cavity; 214, first cavity; 2141, 2142, through hole.

### DETAILED DESCRIPTION OF EMBODIMENTS

To make the objects, technical solutions, and advantages of the embodiments of the present disclosure clearer, hereinafter, the technical solutions in the embodiments of the present application will be described clearly and thoroughly with reference to the accompanying drawings of the embodiments of the present application. Obviously, the embodiments as described are some of the embodiments of the present application, and are not all of the embodiments of the present application. Generally, components in the embodiments of the present application, as described and shown in the drawings herein, may be arranged and designed in a variety of different configurations.

Therefore, the detailed description below of the embodiments of the present application provided in the drawings is not intended to limit the scope of the present application, but merely illustrates chosen embodiments of the present application. It should be noted that various features in the embodiments of the present disclosure may be combined with each other without conflict, and the combined embodiments still fall within the scope of protection of the present disclosure.

In the description of the present application, it should be noted that orientation or position relationships indicated by terms such as “center”, “upper”, “lower”, “left”, “right”, “vertical”, “horizontal”, “inner”, “outer”, etc. are orientation or position relationships based on the accompanying drawings, or are orientation or position relationships of the product of the present application usually placed during use, are only used to facilitate the description of some embodiments of the present application and to simplify the description, rather than indicating or implying that the an apparatus or element referred to thereby must have a specific orientation, and be constructed and operated in the specific orientation, and therefore said terms may not be understood as a limitation to some embodiments of the present disclosure. Moreover, terms such as “first”, “second”, and “third” are used only for distinguishing description and are not to be construed as indicating or implying relative importance.

In the descriptions of the present application, it should be noted that, unless otherwise specified or defined, the terms such as “arrange”, “mount”, “connected” and “connection” should be understood in a broad sense, for example, the connection may be a fixed connection, or an integral connection; may be a direct connection or an indirect connection through an intermediary, and may be an internal communication between two components. For those of ordinary skill in the art, the specific meanings of the above terms in the present application may be understood according to specific situations.

According to an aspect of the embodiments of the present application, provided is a bulk acoustic wave resonator, as shown in FIG. 10, including a substrate 201 and a piezoelectric stack structure stacked on the substrate 201, and the piezoelectric stack structure includes a lower conductive layer 205, a piezoelectric layer 206 and an upper conductive layer 210 which are stacked on the substrate 201 in sequence. It facilitates the mutual conversion of electrical energy and mechanical energy by means of the piezoelectric layer 206 after an alternating current is applied to the upper conductive layer 210 and the lower conductive layer 205.

It should be noted that, the lower conductive layer 205, the piezoelectric layer 206 and the upper conductive layer 210 have an overlapping area in a stacking direction (as shown in FIG. 10, an area a between two dotted lines serves as the overlapping area), which may facilitate the mutual conversion between the electric energy and the mechanical energy between the upper conductive layer 210 and the lower conductive layer 205 in the overlapping area by means of the piezoelectric layer 206. Certainly, in the field, the overlapping area is taken as an effective resonant area. Furthermore, in embodiments having a second cavity 202 located between the substrate 201 and the lower conductive layer 205, an overlapping portion of the second cavity 202 and the overlapping area is also often referred to as an effective resonant area. It is not specifically limited in the present application.

Continue to refer to FIG. 10, at least one first cavity 214 is provided at a boundary of the overlapping area, and the first cavity 214 is located between the upper conductive layer 210 and the piezoelectric layer 206. The formation of the first cavity 214 may be achieved by forming a first sacrificial portion 2071 at an appropriate position between the upper conductive layer 210 and the piezoelectric layer 206 in advance, and then ultimately obtaining by releasing the first sacrificial portion 2071.

Continue to refer to FIG. 10, a plurality of first support columns 2103 are provided in the at least one first cavity 214, and the plurality of first support columns 2103 are arranged in a direction from the center of the overlapping area to the boundary of the overlapping area. In this way, the plurality of first support columns 2103 divide the at least one first cavity 214 into a plurality of through holes, and the plurality of through holes are also arranged in the direction from the center of the overlapping area to the boundary of the overlapping area. Some of the plurality of through holes are located in the overlapping area, or all of the through holes are located in the overlapping area.

In this way, a first acoustic reflection structure is constructed using impedance mismatch formed by the plurality of through holes, the plurality of first support columns 2103 and the upper conductive layer 210, so that transverse acoustic waves may be reflected for many times, thereby conveniently reducing anchor losses, and improving the quality factor. Furthermore, the plurality of first support columns 2103 are supported between the piezoelectric layer 206 and the upper conductive layer 210, so that the at least one first cavity 214 has better strength and stability. Using the plurality of first support columns 2103, the upper conductive layer 210 on the at least one first cavity 214 is lifted away from the piezoelectric layer 206, thereby enhancing the heat dissipation capability of the resonator.

When some of the plurality of through holes are distributed outside the overlapping area, electrical isolation of the non-resonant area may be achieved, and the generation of a piezoelectric effect of the non-resonant area may be reduced, thereby reducing the influence of the pseudo-mode on the target mode.

Optionally, the first acoustic reflection structure may include a plurality of first cavities 214 arranged sequentially along the boundary of the overlapping area. Each of the plurality of first cavities 214 has the corresponding plurality of first support columns 2103 therein for dividing each first cavity into a plurality of through holes. Any two first cavities 214 include the same number of through holes. Or at least two first cavities 214 include different numbers of through holes, in this way, specific settings may be performed according to different degrees of acoustic wave leakage at different positions.

Optionally, there are a plurality of first cavities 214, each of the plurality of first cavities 214 is provided with the plurality of through holes, the plurality of first cavities 214 are arranged at intervals along the boundary of the overlapping area, a connection cavity located between the upper conductive layer 210 and the piezoelectric layer 206 is provided between two adjacent first cavities 214, and the two adjacent first cavities 214 are in communication with each other through the connection cavity. The connection cavity may be obtained by means of releasing at least one third sacrificial portion 2073 filled between the upper conductive layer 210 and the piezoelectric layer 206.

Optionally, the plurality of through holes may be divided into different types of through holes according to position relationships between the through holes and the overlapping area. Specifically, the plurality of through holes include at least one first through hole, the first through hole is located in the overlapping area, the plurality of through holes include at least one second through hole, and the second through hole is located outside the overlapping area. For example, as shown in FIG. 10, the first cavity 214 is divided into four through holes by three first support columns 2103, and the two left-most through holes are the first through holes, and the one right-most through hole is the second through hole. The plurality of through holes may further include a third through hole which crosses the boundary of the overlapping area, for example, as shown in FIG. 10, the first cavity 214 is divided into four through holes by three first support columns 2103, and the third through hole from left to right serves as the third through hole. It is convenient to improve the performance of the resonator.

Optionally, in order to effectively reflect the longitudinal acoustic wave, as shown in FIG. 10, a second cavity 202 is provided between the substrate 201 and the lower conductive layer 205. The second cavity 202 may be formed by etching the front surface of the substrate 201, the front surface of the substrate 201 is a surface near the lower conductive layer 205.

Optionally, orthographic projections, in the stacking direction, of some through holes of the plurality of through holes are located in the second cavity 202, and orthographic projections, in the stacking direction, of the other through holes of the plurality of through holes do not overlap with an orthographic projection of the second cavity 202 in the stacking direction.

Optionally, orthographic projections, in the stacking direction, of the plurality of through holes are located in the second cavity 202.

Optionally, as shown in FIG. 10, orthographic projections, in the stacking direction, of some through holes of the plurality of through holes are located in the second cavity 202, and an orthographic projection, in the stacking direction, of one through hole of the plurality of through holes overlaps with an orthographic projection of the second cavity 202 in the stacking direction. Specifically, as shown in FIG. 10, the first cavity 214 is divided into four through holes by three first support columns 2103, and the orthographic projections, in the stacking direction, of the left-most three through holes are located in the second cavity 202, and the orthographic projection, in the stacking direction, of the right-most one through hole partially overlaps with the orthographic projection of the second cavity 202 in the stacking direction.

Optionally, as shown in FIG. 10, the piezoelectric layer 206 and the lower conductive layer 205 are provided with at least one release hole 212 which is in communication with the second cavity 202, and the at least one release hole 212 is located outside the overlapping area. Certainly, in other embodiments, the at least one release hole 212 may also be located in the overlapping area, or there are a plurality of release holes 212, some of the plurality of release holes 212 are located outside the overlapped area, and the other release holes 212 of the plurality of release holes 212 are located in the overlapping area.

Optionally, as shown in FIG. 10, each of the plurality of the through holes has a width in a direction from the center of the overlapping area to the boundary of the overlapping area, and at least some of the plurality of through holes have different widths. In other words, the width of the through hole is a distance between two adjacent first support columns 2103. In other embodiments, the widths of all of the plurality of through holes are the same.

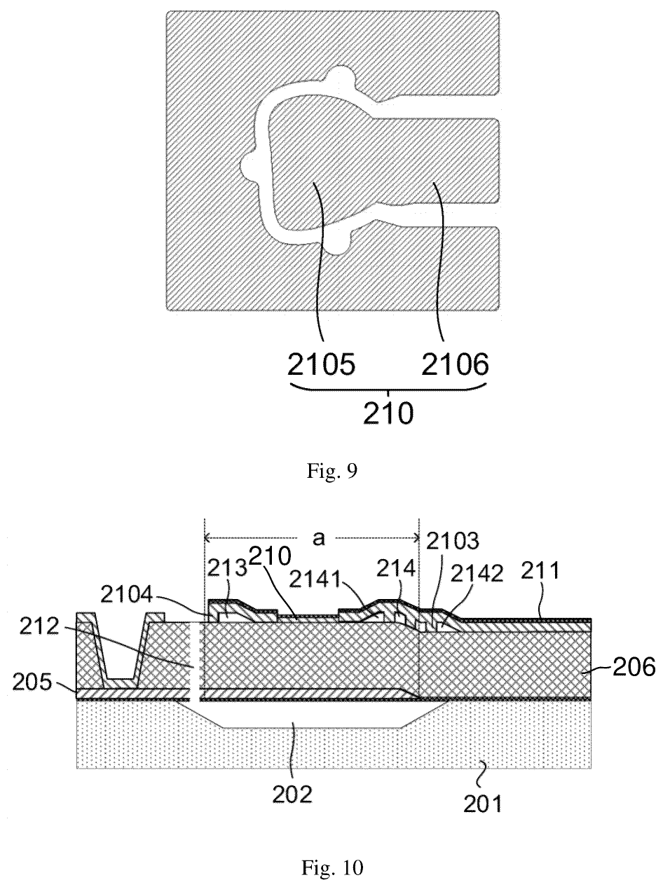

Optionally, as shown in FIG. 8, the upper conductive layer 210 has an anchor portion 2101, the anchor portion 2101 is located on the at least one first cavity 214, and a surface of one side of the anchor portion 2101 away from the piezoelectric layer is an undulating surface 206.

Optionally, as shown in FIG. 9, the upper conductive layer 210 includes an upper electrode 2105 located in the overlapping area and an upper electrode lead-out portion 2106 located outside the overlapping area; a peripheral edge of the upper electrode 2105 is composed of a first edge and a second edge, and the first edge and the second edge are connected; and the upper electrode 2105 is connected to the upper electrode lead-out portion 2106 through the first edge.

Optionally, the length of the first edge may be increased to decrease the connection resistance of the upper electrode lead-out portion 2106.

Optionally, the at least one first cavity 214 is located at the first edge, that is, the at least one first cavity 214 is distributed along the first edge. Or the at least one first cavity 214 may be located at the first edge and the second edge, that is, the at least one first cavity 214 is distributed along the first edge and the second edge. In other words, the distribution length of the first acoustic reflection structure may be less than, equal to or greater than the length of the first edge. When the distribution length of the first acoustic reflection structure is greater than the length of the first edge, a part of the first cavity 214 in the first acoustic reflection structure may be located at the first edge, and the other part of the first cavity 214 may be located at the second edge.

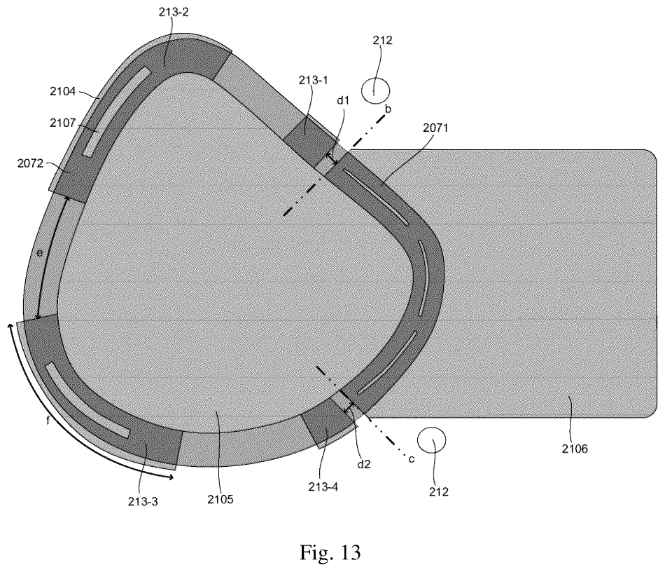

For better understanding, as shown in FIG. 13, a first position is defined by a first separation line b on an edge of the upper electrode 2105, and a second position is defined by a second separation line c, and in a clockwise direction, an edge length (hereinafter referred to as a first distribution length for ease of understanding) from the first separation line b to the second separation line c is equal to the length of the first edge, and an edge length (hereinafter referred to as a second distribution length for ease of understanding) from the second separation line c to the first separation line b is equal to the length of the second edge. All of the first cavities 214 are distributed over the first distribution length.

Certainly, in other embodiments, the first distribution length may be greater than the length of the first edge, that is, the first distribution length, in addition to the first edge, further includes the length of a part of the second edge. Correspondingly, the second distribution length is less than the length of the second edge. The first position and the second position may be reasonably set according to actual requirements. It may be understood that by varying the first position and the second position, the effective electromechanical coupling factor of the resonator may be adjusted.

Optionally, as shown in FIG. 10, at least one third cavity 213 is provided between the upper electrode 2105 and the piezoelectric layer 206, and the at least one third cavity 213 is located at the second edge, so that a second acoustic reflection structure is formed by the at least one third cavity 213 and the upper electrode 2105. By utilizing the impedance mismatch formed by the at least one third cavity 213 and the upper electrode 2105, the second acoustic reflection structure may reflect the transverse acoustic wave, thereby enhancing the quality factor.

Optionally, as shown in FIG. 10, a side of the third cavity 213 away from the center of the overlapping area is closed by at least one second support column 2104 supported between the upper electrode 2105 and the piezoelectric layer 206. On the one hand, the at least one second support column 2104 may cooperate with the third cavity 213 to form an impedance mismatch, so that the second acoustic reflection structure constructed by the at least one third cavity 213, the upper electrode 2105 and the at least one second support column 2104 may form a double-ended closing structure, that is, both the left side and the right side of the third cavity 213 are closed in FIG. 10. In this way, the quality factor may be effectively improved, and furthermore, the heat dissipation at the second edge of the upper electrode 2105 may also be ensured.

Optionally, as shown in FIG. 10, the first cavity 214 includes a plurality of through holes, and the plurality of through holes include a through hole 2141 closest to the center of the overlapping area and a through hole 2142 farthest from the center of the overlapping area, and the bottom plane of the through hole 2141 is parallel to the bottom plane of the through hole 2142, a plurality of through holes are spaced between the bottom plane of the through hole 2141 and the bottom plane of the through hole 2142, and the bottom planes of the two are parallel to each other, which may further reflect a transverse acoustic wave in an obliquely downward direction, thereby improving the quality factor.

Optionally, as shown in FIG. 13, at least one third support column 2107 supported between the upper electrode 2105 and the piezoelectric layer 206 is provided in the third cavity 213. The third support column 2107 may divide the third cavity 213 into two portions arranged along the direction from the center of the overlapping area to the edge of the overlapping area, thereby realizing continuous sound reflection.

It should be noted that the materials of the first support column 2103, the second support column 2104 and the third support column 2107 may be the same as or different from that of the upper conductive layer 210, which is not specifically limited in the present application. When the first support column 2103, the second support column 2104, the third support column 2107 and the upper conductive layer 210 are all made of a metal material, the first support column 2103, the second support column 2104, the third support column 2107 and the upper conductive layer 210 may be obtained by patterning the same metal layer.

Optionally, there are a plurality of third cavities 213, and the plurality of third cavities 213 are arranged at intervals along the second edge. Specifically, the plurality of third cavity 213 may be formed by means of a second sacrificial portion 2072, that is, the second sacrificial portion 2072 may be pre-filled between the upper electrode 2105 and the piezoelectric layer 206, and ultimately, by releasing the second sacrificial portion 2072, the space originally occupied by the second sacrificial portion 2072 forms the plurality of third cavity 213. Therefore, as shown in FIG. 13, after the upper conductive layer 210 covering the first sacrifice portion 2071 and the second sacrifice portion 2072 is formed on the first sacrifice portion 2071 and the second sacrifice portion 2072, the second sacrifice portion 2072 may be finally released, thereby forming the third cavity 213-1, the third cavity 213-2, the third cavity 213-3, and the third cavity 213-4.

Optionally, the at least one third cavity 213 is spaced apart from an endpoint of the first edge by a first distance, the first distance is greater than 5 microns. Specifically, for example, as shown in FIG. 13, the length of the first edge is equal to the first distribution length, and therefore, the first position of the first separation line b on the edge of the upper electrode 2105 may be taken as an endpoint of the first edge; likewise, the second position of the second separation line c on the edge of the upper electrode 2105 may be taken as another endpoint of the first edge, and the distance d1 from the third cavity 213-1 adjacent to the first position to the first position is a first distance, which should be greater than 5 microns; likewise, the distance d2 from the third cavity 213-4 adjacent to the second position to the second position is the first distance, which should also be greater than 5 microns. Thus, the resonator has a better performance.

Optionally, when the piezoelectric layer 206 and the lower conductive layer 205 are provided with at least one release hole 212 in communication with the second cavity 202, an orthographic projection of the release hole 212 in the stacking direction are located outside an orthographic projection of the upper electrode lead-out portion 2106 in the stacking direction. Thus, the upper electrode lead-out portion 2106 has a better lead-out performance. Specifically, for example, in a top view shown in FIG. 13, the release holes 212 may be distributed at upper and lower sides of the upper electrode lead-out portion 2106.

Optionally, as shown in FIG. 10, when a second cavity 202 is provided between the substrate 201 and the lower conductive layer 205, an orthographic projection of at least one third cavity 213 in the stacking direction is located in the second cavity 202, so that the resonator has a better performance.

Optionally, as shown in FIG. 10, each of the plurality of through holes has a width in the direction (a direction from the left to the right in FIG. 10) from the center of the overlapping area to the boundary of the overlapping area, the at least one third cavity 213 has a width in the direction (a direction from the right to the left in FIG. 10) from the center of the overlapping area to the boundary of the overlapping area, and the width of the at least one third cavity 213 is greater than a sum of widths of any two through holes and less than a sum of widths of any three through holes, so that the resonator has a better performance.

Optionally, as shown in FIG. 8, the upper conductive layer 210 has an anchor portion 2101 located on the at least one first cavity 214, the anchor portion 2101 has a first surface away from one side of the piezoelectric layer 206, the upper conductive layer 210 has a wing portion 2102 located on the third cavity 213, the wing portion 2102 has a second surface away from one side of the piezoelectric layer 206, and a maximum spacing between the first surface and a back surface of the substrate 201 is different from a maximum spacing between the second surface and the back surface of the substrate 201, the back surface of the substrate 201 is a surface of the substrate 201 away from the lower conductive layer 205. In other words, a highest point of the anchor portion 2101 (the point farthest from the back surface of the substrate 201) has a height difference from a highest point of the wing portion 2102 (the point farthest from the back surface of the substrate 201).

the present application provides the bulk acoustic resonator and the manufacturing method therefor, the bulk acoustic resonator including the substrate, and the lower conductive layer, the piezoelectric layer and the upper conductive layer which are sequentially stacked on the substrate, and the lower conductive layer, the piezoelectric layer and the upper conductive layer have the overlapping area in the stacking direction; the at least one first cavity located between the upper conductive layer and the piezoelectric layer is provided at the boundary of the overlapping area; the plurality of first support columns are provided in the at least one first cavity, the plurality of first support columns are used for dividing the at least one first cavity into the plurality of through holes at least partially located in the overlapping area; and the plurality of through holes are arranged in the direction from the center of the overlapping area to the boundary. A first acoustic reflection structure is constructed using impedance mismatch formed by the plurality of through holes, the plurality of first support columns and the upper conductive layer, so that transverse acoustic waves may be reflected for many times, thereby conveniently reducing anchor losses, and improving the quality factor. Furthermore, the plurality of first support columns are supported between the piezoelectric layer and the upper conductive layer, so that the at least one first cavity has better strength and stability. Using the plurality of first support columns, the upper conductive layer on the at least one first cavity is lifted away from the piezoelectric layer, thereby enhancing the heat dissipation capability of the resonator.

According to another aspect of the embodiments of the present application, provided is a method for manufacturing a bulk acoustic wave resonator. Refer to FIGS. 1 to 10, the method includes:

Step 1: a lower conductive layer 205 and a piezoelectric layer 206 are formed on a substrate 201.

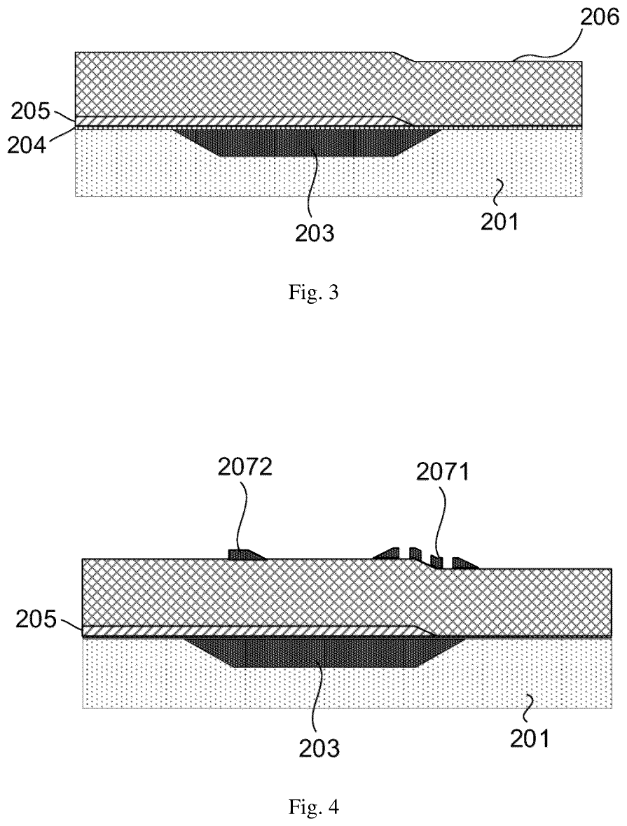

As shown in FIG. 1, the substrate 201 is first provided, and then as shown in FIG. 3, the lower conductive layer 205 and the piezoelectric layer 206 are formed on the substrate 201. Furthermore, in order to improve the quality of the lower conductive layer 205, before forming the lower conductive layer 205, a seed layer 204 may be deposited on the substrate 201, and then the lower conductive layer 205 is manufactured on the seed layer 204.

Step 2: A plurality of first sacrificial portions 2071, an upper conductive layer 210 covering the plurality of first sacrificial portions 2071, and a plurality of first support columns 2103 filled between two adjacent first sacrificial portions 2071 are formed on the piezoelectric layer 206, and the lower conductive layer 205, the piezoelectric layer 206 and the upper conductive layer 210 have an overlapping area in an overlapping direction, the plurality of first sacrificial portions 2071 are at least partially located in the overlapping area, and the plurality of first sacrificial portions 2071 are arranged at intervals in a direction from a center of the overlapping area to a boundary of the overlapping area.

As shown in FIG. 4, the plurality of first sacrificial portions 2071 are first formed on the piezoelectric layer 206, the plurality of first sacrificial portions 2071 are at least partially located in the overlapping area, and the plurality of first sacrificial portions 2071 are arranged at intervals in the direction from the center of the overlapping area to the boundary of the overlapping area.

As shown in FIG. 6, the piezoelectric layer 206 may be etched to form a lower conductive layer lead-out hole 208. Then, a thickening layer 209 covering the plurality of first sacrificial portions 2071 is first formed on the piezoelectric layer 206, and the first support column 2103 is filled between every two adjacent first sacrificial portions 2071. Then, as shown in FIG. 8, a connection layer is further formed on the piezoelectric layer 206 and the thickening layer 209, so that the upper conductive layer 210 is formed by the connection layer and the thickening layer 209 together. When the first support column 2103 and the upper conductive layer 210 are both made of metal material, the first support column 2103 and the upper conductive layer 210 may be obtained by patterning the same metal layer.

Step 3: The plurality of first sacrificial portions 2071 are released to form at least one first cavity 214 between the upper conductive layer 210 and the piezoelectric layer 206, and the at least one first cavity 214 is divided by the plurality of first support columns 2103 into a plurality of through holes arranged in the direction from the center of the overlapping area to the boundary of the overlapping area.

As shown in FIG. 10, the plurality of first sacrificial portions 2071 are released, thereby forming the at least one first cavity 214 between the upper conductive layer 210 and the piezoelectric layer 206, and the at least one first cavity 214 is divided by the plurality of first support columns 2103 into the plurality of through holes arranged in the direction from the center of the overlapping area to the boundary of the overlapping area. The plurality of through holes are positioned at least partially in the overlapping area.

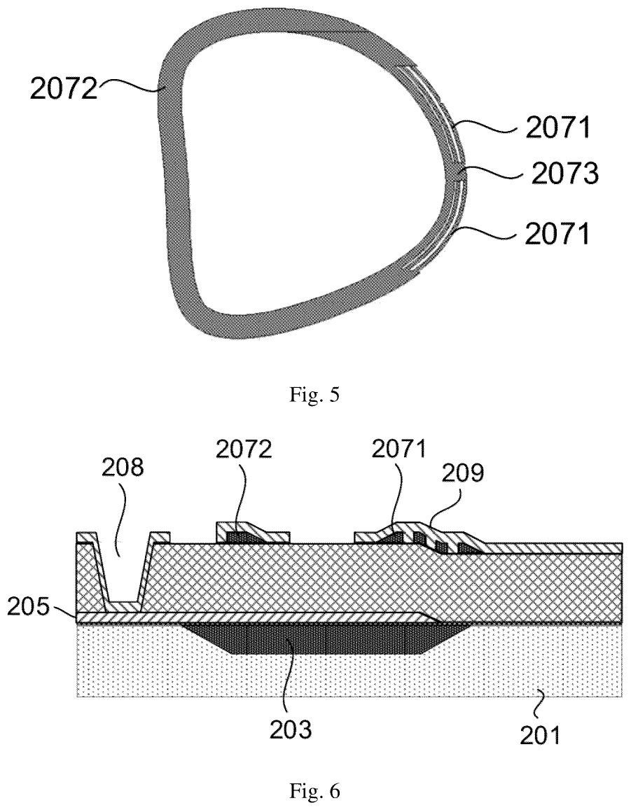

Optionally, the plurality of first sacrificial portions 2071, the upper conductive layer 210 covering the plurality of first sacrificial portions 2071, and the plurality of first support columns 2103 filled between two adjacent first sacrificial portions 2071 are formed on the piezoelectric layer 206 includes: as shown in FIG. 4, firstly a first sacrificial layer is formed on the piezoelectric layer 206, and then the first sacrificial layer is etched to obtain the plurality of first sacrificial portions 2071 and a second sacrificial portion 2072. In conjunction with the top view as shown in FIG. 5, in order to facilitate release, the first sacrificial portion 2071 and the second sacrificial portion 2072 may be connected by means of an intermediate sacrificial portion to form a sacrificial layer to be released. The plurality of first sacrificial portions 2071 may be arranged according to the positions and quantity of through holes to be finally formed. The width of the first sacrificial portion 2071 is the width of the through holes, and the width of the second sacrificial portion 2072 is the width of the third cavity 213.

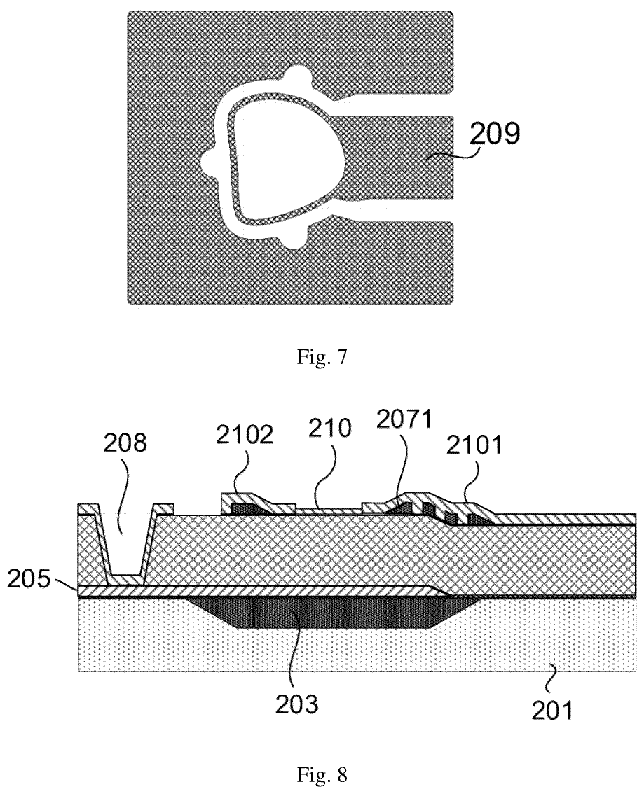

As shown in FIGS. 6 and 7, a thickening layer 209 covering the plurality of first sacrificial portions 2071 and the at least one second sacrificial portion 2072, the plurality of first support columns 2103, the at least one second support column 2104, and at least one third support column 2107 are formed on the piezoelectric layer 206. Then, as shown in FIGS. 8 and 9, a connection layer is formed on the piezoelectric layer 206 and the thickening layer 209, so that the upper conductive layer 210 is formed by the connection layer and the thickening layer 209 together. The at least one second sacrificial portion 2072 is used for releasing to form the at least one third cavity 213 located between the upper conductive layer 210 and the piezoelectric layer 206, the upper conductive layer 210 includes an upper electrode 2105 located in the overlapping area and an upper electrode lead-out portion 2106 located outside the overlapping area, a peripheral edge of the upper electrode 2105 is composed of a first edge and a second edge, the upper electrode 2105 is connected to the upper electrode lead-out portion 2106 by means of the first edge, and the at least one third cavity 213 is located at the second edge; and the first cavity 214 is located at the first edge, or the first cavity 214 is located at the first edge and the second edge.

As shown in FIG. 5, when there are two first cavities 214, the two first cavities 214 may communicate with each other through a connection cavity. Since the two first cavity 214 is formed by means of release of a plurality of first sacrificial portion 2071 and the connection cavity is formed by means of release of at least one third sacrificial portion 2073, FIG. 5 shows the structure of a sacrificial layer to be released in a top viewing angle, and the sacrificial layer to be released includes the third sacrificial portion 2073 used for forming a connection cavity, the plurality of first sacrificial portions 2071 used for forming the two first cavities 214 are formed on both sides of the third sacrificial portion 2073, and the third sacrificial portion 2073 is respectively connected to the plurality of first sacrificial portions 2071 on both sides thereof, so that after the sacrificial layer to be released is released, the two first cavities 214 are in communication with each other by means of the connection cavity. The sacrificial layer to be released further includes a second sacrificial portion 2072 and an intermediate connection portion. The width of the intermediate connection, the width of the second sacrificial portion 2072, and the overall width of the plurality of first sacrificial portions 2071 used to form the two first cavities 214 are similar or equal.

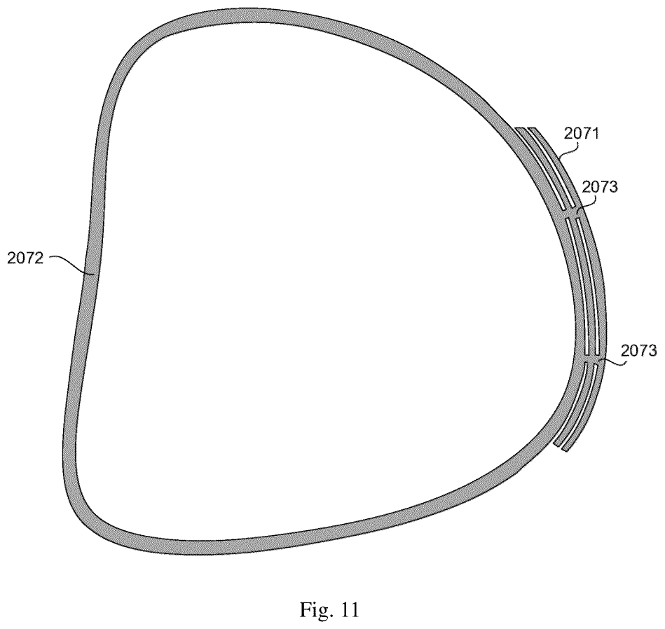

When there are three first cavities 214, the three first cavities 214 may communicate with each other through two connection cavities. Correspondingly, FIG. 11 shows the structure of a sacrificial layer to be released in a top view angle, and the sacrificial layer to be released includes three first sacrificial portions 2071 used for respectively forming three first cavities 214, two third sacrificial portions 2073 and three first sacrificial portions 2071 are distributed alternately; and after the sacrificial layer to be released is released, two adjacent first cavities 214 are in communication with each other through a connection cavity therebetween. The sacrificial layer to be released further includes a second sacrificial portion 2072 and an intermediate connection portion. The width of the intermediate connection portion and the width of the second sacrificial portion 2072 are substantially different from the overall width of the plurality of first sacrificial portions 2071 used for forming the first cavity 214, and the width of the intermediate connection portion and the width of the second sacrificial portion 2072 are relatively narrow.

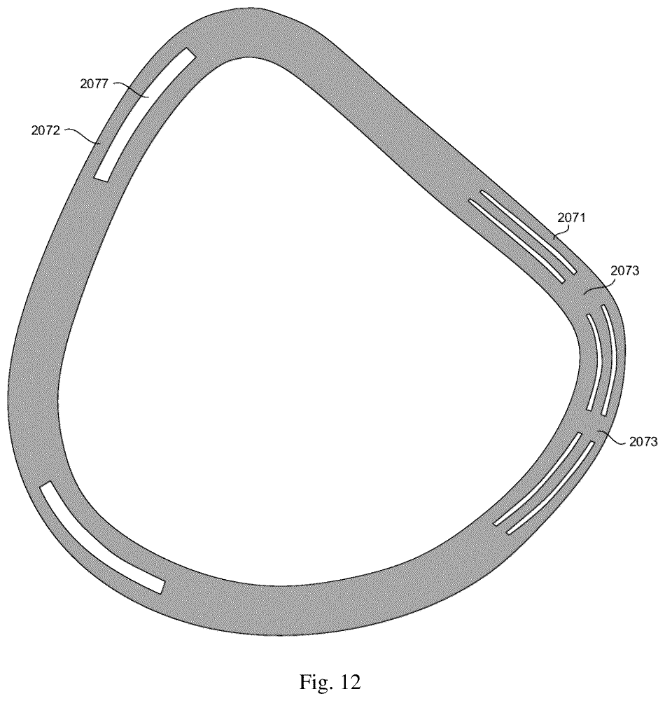

When there are three first cavities 214, the three first cavities 214 may communicate with each other through two connection cavities. Correspondingly, FIG. 12 shows the structure of a sacrificial layer to be released in a top view angle, and the sacrificial layer to be released includes three first sacrificial portions 2071 used for respectively forming three first cavities 214; two third sacrificial portions 2073 and three first sacrificial portions 2071 are distributed alternately; and after the sacrificial layer to be released is released, two adjacent first cavities 214 are in communication with each other through a connection cavity therebetween. The sacrificial layer to be released further includes a second sacrificial portion 2072 and an intermediate connection portion. The sacrificial layer to be released further includes a second sacrificial portion 2072 and an intermediate connection portion. The width of the intermediate connection, the width of the second sacrificial portion 2072, and the overall width of the plurality of first sacrificial portions 2071 used to form the first cavity 214 are similar or equal. In addition, at least one gap 2077 for forming at least one third support column 2107 is provided in the second sacrificial portion 2072.

The effective electromechanical coupling factor of the bulk acoustic wave resonator of the present application may be adjusted by changing any one or more of the width of the through hole, the number of the through holes, the width of the first support column 2103, and the number of the connection cavities.

Optionally, as shown in FIG. 13, along a peripheral edge of the upper electrode 2105, a third cavity 213 with a length of a third distance f is provided at an interval of a second distance e.

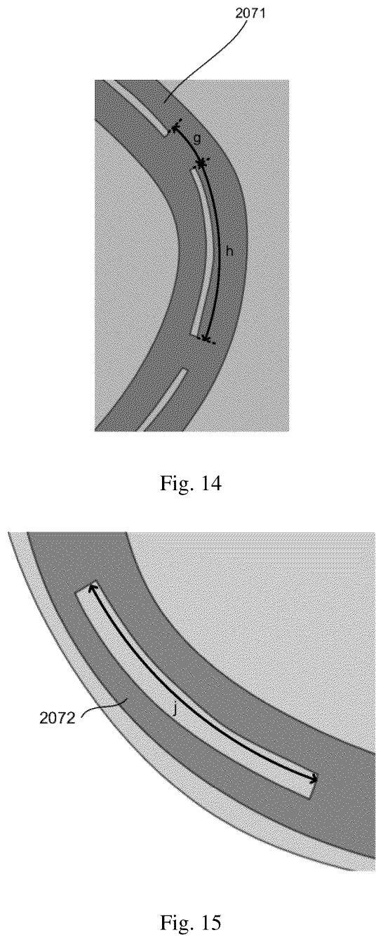

Optionally, as shown in FIG. 14, along a peripheral edge of the upper electrode 2105, a first support column 2103 with a length of a fifth distance h is provided at an interval of a fourth distance g.

Optionally, as shown in FIG. 15, along a peripheral edge of the upper electrode 2105, a third support column 2107 with a length of a sixth distance j is provided in the third cavity 213.

Optionally, when adjusting the effective electromechanical coupling factor and the quality factor of the bulk acoustic wave resonator of the present application, the effective electromechanical coupling factor and the quality factor may be adjusted by changing any one or more of the second distance e, the third distance f, the fourth distance g, the fifth distance h, and the sixth distance j.

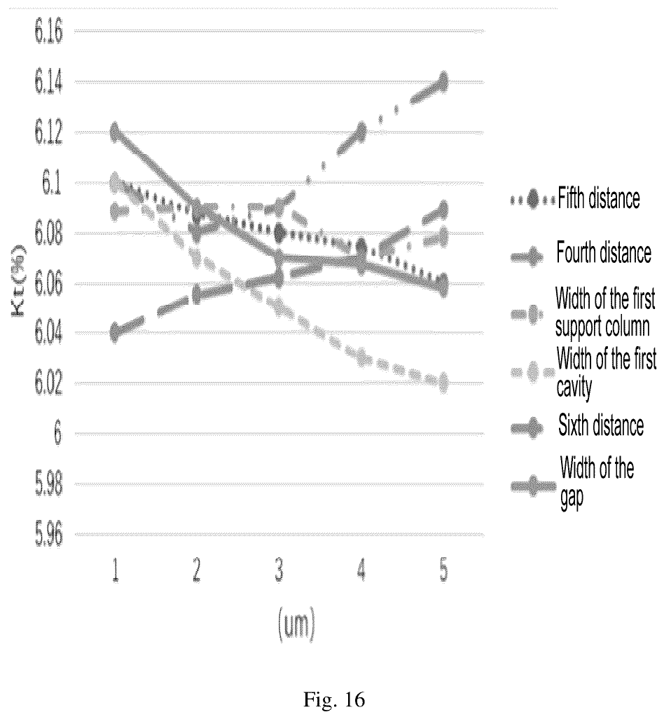

For example, refer to FIG. 16, by changing one of the fifth distance h, the fourth distance g, the width of the first support column 2103, the width of the first cavity 214, the sixth distance j, and the width of the gap, the effective electromechanical coupling factor Kt of the bulk acoustic wave resonator may be adjusted correspondingly. The effective electromechanical coupling factor Kt serves as a longitudinal coordinate; the fifth distance h, the fourth distance g, the width of the first support column 2103, the width of the first cavity 214, the sixth distance j, and the width of the gap serve as transverse coordinates; specifically, within the range of 0-5 microns, the effective electromechanical coupling factor Kt gradually decreases as the fifth distance h increases; within the range of 0-5 microns, the effective electromechanical coupling factor Kt first decreases and then increases as the fourth distance g increases; within the range of 0-5 microns, the effective electromechanical coupling factor Kt first increases, then decreases and then increases as the width of the first support column 2103 increases; within the range of 0-5 microns, the effective electromechanical coupling factor Kt gradually decreases as the width of the first cavity 214 increases; within the range of 0-5 microns, the effective electromechanical coupling factor Kt gradually increases as the sixth distance j increases; and within the range of 0-5 microns, the effective electromechanical coupling factor Kt gradually decreases as the width of the gap increases.

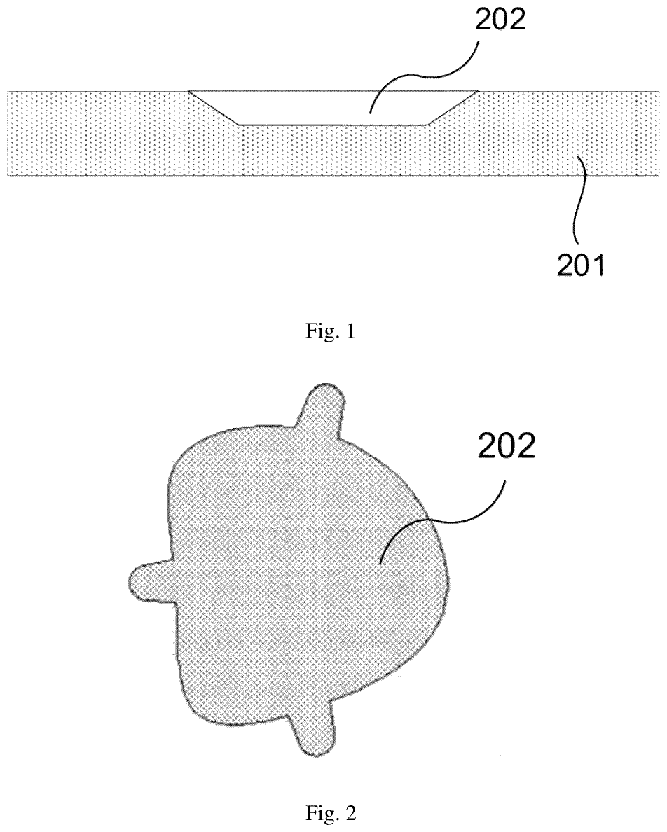

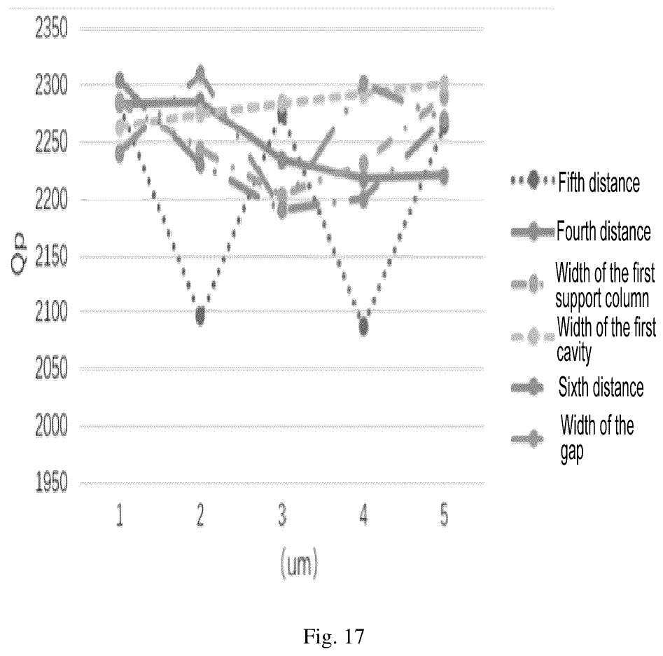

For example, refer to FIG. 17, by changing one of the fifth distance h, the fourth distance g, the width of the first support column 2103, the width of the first cavity 214, the sixth distance j, and the width of the gap, the quality factor Qp of the bulk acoustic wave resonator may be adjusted correspondingly. The quality factor Qp serves as a longitudinal coordinate; the fifth distance h, the fourth distance g, the width of the first support column 2103, the width of the first cavity 214, the sixth distance j, and the width of the cavity serve as transverse coordinates. Specifically, within the range of 0-5 microns, the quality factor Qp decreases firstly, then increases, then decreases, then increases again as the fifth distance h increases; within the range of 0-5 microns, the quality factor Qp increases firstly, then decreases and then increases as the fourth distance g increases; within the range of 0-5 microns, the quality factor Qp decreases first and then increases as the width of the first support column 2103 increases; within the range of 0-5 microns, the quality factor Qp increases gradually as the width of the first cavity 214 increases; within the range of 0-5 microns, the quality factor Qp decreases first and then increases as the sixth distance j increases; and within the range of 0-5 microns, the quality factor Qp increases, then decreases, then increases and then gradually decreases as the width of the gap increases. Optionally, as shown in FIG. 1, the second cavity 202 may be formed on the substrate 201 by etching. In a top view shown in FIG. 2, the second cavity 202 may be an irregular pattern. Certainly, as shown in FIG. 3, in order to facilitate the subsequent formation of the seed layer 204, the lower conductive layer 205 and the like on the substrate 201, the second cavity 202 may be filled first by means of the second sacrificial layer 203, and by means of a flattening process, an upper surface of the second sacrificial layer 203 in the second cavity 202 is flush with the front surface of the substrate 201.

Optionally, as shown in FIG. 10, a protective layer 211 may also be formed on the upper conductive layer 210.

The content above merely relates to preferred embodiments of the present application and is not intended to limit the present application. For a person skilled in the art, the present application may have various modifications and variations. Any modifications, equivalent replacements, improvements, etc. made within the spirit and principle of the present application shall all belong to the scope of protection of the present application.

What is claimed is:

1. A bulk acoustic wave resonator, comprising a substrate, and a lower conductive layer, a piezoelectric layer and an upper conductive layer which are sequentially stacked on the substrate,
wherein the lower conductive layer, the piezoelectric layer and the upper conductive layer have an overlapping area in a stacking direction;
at least one first cavity located between the upper conductive layer and the piezoelectric layer is provided at a boundary of the overlapping area;
a plurality of first support columns are provided in the at least one first cavity, the plurality of first support columns are used for dividing the at least one first cavity into a plurality of through holes at least partially located in the overlapping area; and
the plurality of through holes are arranged in a direction from a center of the overlapping area to the boundary of the overlapping area.

2. The bulk acoustic wave resonator as claimed in claim 1, wherein there are a plurality of first cavities, each of the plurality of first cavities is provided with the plurality of through holes, the plurality of first cavities are arranged at intervals along the boundary of the overlapping area, a connection cavity located between the upper conductive layer and the piezoelectric layer is provided between two adjacent first cavities, and the two adjacent first cavities are in communication with each other through the connection cavity.

3. The bulk acoustic wave resonator as claimed in claim 2, wherein among the plurality of first cavities, at least two first cavities comprise different numbers of through holes.

4. The bulk acoustic wave resonator as claimed in claim 1, wherein the plurality of through holes comprises at least one of the following:
at least one first through hole located in the overlapping area and at least one second through hole located outside the overlapping area; and
a third through hole crossing the boundary of the overlapping area.

5. The bulk acoustic wave resonator as claimed in claim 1, wherein a second cavity is provided between the substrate and the lower conductive layer;
orthographic projections, in the stacking direction, of the plurality of through holes are located in the second cavity; or
orthographic projections, in the stacking direction, of some through holes of the plurality of through holes are located in the second cavity, and orthographic projections, in the stacking direction, of the other through holes of the plurality of through holes do not overlap with an orthographic projection of the second cavity in the stacking direction.

6. The bulk acoustic wave resonator as claimed in claim 5, wherein the piezoelectric layer and the lower conductive layer are provided with at least one release hole which is in communication with the second cavity, and the at least one release hole is located outside the overlapping area.

7. The bulk acoustic wave resonator as claimed in claim 1, wherein each of the plurality of through holes has a width in the direction from the center of the overlapping area to the boundary of the overlapping area, and at least some of the plurality of through holes have different widths.

8. The bulk acoustic wave resonator as claimed in claim 1, wherein the upper conductive layer has an anchor portion, the anchor portion is located on the at least one first cavity, and a surface of one side of the anchor portion away from the piezoelectric layer is an undulating surface.

9. The bulk acoustic wave resonator as claimed in claim 1, wherein the upper conductive layer comprises an upper electrode located in the overlapping area and an upper electrode lead-out portion located outside the overlapping area, a peripheral edge of the upper electrode is composed of a first edge and a second edge, and the upper electrode is connected to the upper electrode lead-out portion by means of the first edge; and the at least one first cavity is located at the first edge, or the at least one first cavity is located at the first edge and the second edge.

10. The bulk acoustic wave resonator as claimed in claim 9, wherein at least one third cavity is provided between the upper electrode and the piezoelectric layer, and the at least one third cavity is located at the second edge.

11. The bulk acoustic wave resonator as claimed in claim 10, wherein a side of the at least one third cavity away from the center of the overlapping area is closed by at least one second support column supported between the upper electrode and the piezoelectric layer.

12. The bulk acoustic wave resonator as claimed in claim 10, wherein at least one third support column supported between the upper electrode and the piezoelectric layer is provided in the third cavity.

13. The bulk acoustic wave resonator as claimed in claim 10, wherein there are a plurality of third cavities, and the plurality of third cavities are arranged at intervals along the second edge.

14. The bulk acoustic wave resonator as claimed in claim 10, wherein when a second cavity is provided between the substrate and the lower conductive layer, an orthographic projection of the at least one third cavity in the stacking direction is located in the second cavity.

15. The bulk acoustic wave resonator as claimed in claim 10, wherein each of the plurality of through holes has a width in the direction from the center of the overlapping area to the boundary of the overlapping area, the at least one third cavity has a width in the direction from the center of the overlapping area to the boundary of the overlapping area, and the width of the at least one third cavity is greater than a sum of widths of any two through holes and less than a sum of widths of any three through holes.

16. The bulk acoustic wave resonator as claimed in claim 10, wherein the upper conductive layer has an anchor portion located on the at least one first cavity, the anchor portion has a first surface away from one side of the piezoelectric layer, the upper conductive layer has a wing portion located on the at least one third cavity, the wing portion has a second surface away from one side of the piezoelectric layer, and a maximum spacing between the first surface and a back surface of the substrate is different from a maximum spacing between the second surface and the back surface of the substrate.

17. The bulk acoustic wave resonator as claimed in claim 9, wherein when the piezoelectric layer and the lower conductive layer are provided with at least one release hole in communication with the second cavity, an orthographic projection of the at least one release hole in the stacking direction are located outside an orthographic projection of the upper electrode lead-out portion in the stacking direction.

18. The bulk acoustic wave resonator as claimed in claim 10, wherein the at least one third cavity is spaced apart from an endpoint of the first edge by a first distance, the first distance is greater than 5 microns.

19. A method for manufacturing a bulk acoustic wave resonator, comprising:
forming a lower conductive layer and a piezoelectric layer on a substrate;
forming, on the piezoelectric layer, a plurality of first sacrificial portions, an upper conductive layer covering the plurality of first sacrificial portions, and a plurality of first support columns each of which filled between two adjacent first sacrificial portions, wherein the lower conductive layer, the piezoelectric layer and the upper conductive layer have an overlapping area in an overlapping direction, the plurality of first sacrificial portions are at least partially located in the overlapping area, and the plurality of first sacrificial portions are arranged at intervals in a direction from a center of the overlapping area to a boundary of the overlapping area; and
releasing the plurality of first sacrificial portions to form at least one first cavity between the upper conductive layer and the piezoelectric layer, wherein the at least one first cavity is divided by the plurality of first support columns into a plurality of through holes arranged in the direction from the center of the overlapping area to the boundary of the overlapping area.

20. The method for manufacturing the bulk acoustic wave resonator as claimed in claim 19, wherein forming, on the piezoelectric layer, the plurality of first sacrificial portions, the upper conductive layer covering the plurality of first sacrificial portions, and the plurality of first support columns each of which filled between two adjacent first sacrificial portions comprises:
forming a first sacrificial layer on the piezoelectric layer;
etching the first sacrificial layer to form the plurality of first sacrificial portions and a second sacrificial portion; and
forming, on the piezoelectric layer, an upper conductive layer covering the plurality of first sacrificial portions and the second sacrificial portion, and the plurality of first support column each of which filled between two adjacent first sacrificial portions, wherein the second sacrificial portion is used for releasing to form at least one third cavity located between the upper conductive layer and the piezoelectric layer, the upper conductive layer comprises an upper electrode located in the overlapping area and an upper electrode lead-out portion located outside the overlapping area, a peripheral edge of the upper electrode is composed of a first edge and a second edge, the upper electrode is connected to the upper electrode lead-out portion by means of the first edge, and the at least one third cavity is located at the second edge; and the at least one first cavity is located at the first edge, or the at least one first cavity is located at the first edge and the second edge.
